(19) United States
(12) Patent Application Publication
(10) Pub. No.: US 2026/0049396 A1
(43) Pub. Date: Feb. 19, 2026

(54) MULTI-STATION SUBSTRATE PROCESSING CHAMBER WITH PRECISE TEMPERATURE AND FLOW CONTROL

(71) Applicant: Applied Materials, Inc., Santa Clara, CA (US)

(72) Inventor: Rohit Ode, Morgan Hill, CA (US)

(73) Assignee: Applied Materials, Inc., Santa Clara, CA (US)

(21) Appl. No.: 18/804,980

(22) Filed: Aug. 14, 2024

(51) Int. Cl. C23C 16/455; C23C 16/458; C23C 16/52; H01J 37/32; H05B 1/02

(52) U.S. Cl. CPC C23C 16/45548; C23C 16/458; C23C 16/52; H01J 37/32522; H05B 1/0233; H01J 2237/3321; H01J 2237/3323

(57) ABSTRACT

Multiple station substrate processing chambers and methods are provided comprising four spatially separated substrate processing stations within a chamber wall are described. Independently controlled heating zones to the each of four spatially separated substrate processing stations and independently heated supply lines improve deposition uniformity of substrates simultaneously processed in each of the each of four spatially separated substrate processing stations.

### TECHNICAL FIELD

Embodiments of the disclosure are directed to multiple station substrate processing chambers including film deposition uniformity control. In particular, embodiments of the disclosure pertain to precursor supply conduit and delivery conf temperature control for multi-station processing of semiconductor substrates.

### BACKGROUND

Film deposition methods utilized in semiconductor manufacturing are highly temperature dependent. Variations in temperature across a substrate surface can lead to non-uniform deposition and ultimately device failure and/or decreased throughput. Therefore, there is a need for temperature control across during processing.

Current atomic layer deposition (ALD) processes have a number of potential issues and difficulties. Many ALD chemistries (e.g., precursors and reactants) are “incompatible,” which means that the chemistries cannot be mixed together. If the incompatible chemistries mix, a chemical vapor deposition (CVD) process, instead of the ALD process could occur. The CVD process generally has less thickness control than the ALD process and/or can result in the creation of gas phase particles which can cause defects in the resultant device. For a traditional time-domain ALD process in which a single reactive gas is flowed into the processing chamber at a time, a long purge/pump out time occurs so that the chemistries are not mixed in the gas phase. A spatial ALD chamber can move one or more substrate(s) from one environment to a second environment faster than a time-domain ALD chamber can pump/purge, resulting in higher throughput.

The semiconductor industry requires high quality films which can be deposited at lower temperatures (e.g., below 350° C.). To deposit high quality films at temperatures below where the film would be deposited with a thermal only process, alternative energy sources are needed. Plasma solutions can be used to provide the additional energy in the form of ions and radicals to the ALD film. The challenge is to get sufficient energy on the vertical side wall ALD film. Ions typically are accelerated through a sheath above the substrate surface in a direction normal to the substrate surface. Therefore, the ions provide energy to horizontal ALD film surfaces, but provide an insufficient amount of energy to the vertical surfaces because the ions moving parallel to the vertical surfaces.

Recent advances in substrate processing chamber design comprise multiple substrate processing environments within a single processing chamber. In an example of a multiple substrate processing in a single processing chamber, four substrates are simultaneously processed using the same deposition process.

Tight temperature control of the precursor delivered to each of the substrates simultaneously processed in a single processing chamber is needed for uniform deposition and reproducible processing for the multiple substrates. Therefore, there is a need for precursor temperature control in the delivery of precursor to multiple substrates within a single processing chamber.

### SUMMARY

One or more embodiments are directed to a multiple station substrate processing chamber comprising a chamber wall enclosing four spatially separated substrate processing stations configured to separately and simultaneously deposit a film on a substrate placed within each of the four spatially separated substrate processing stations; a first delivery conduit configured to deliver a first precursor through a first heating zone to a gas distribution faceplate in a first spatially separated substrate processing station and a second heating zone to a gas distribution faceplate in a second spatially separated substrate processing station; a second delivery conduit configured to deliver a second precursor through a third heating zone to the gas distribution faceplate in the first spatially separated substrate processing station and a fourth heating zone to a gas distribution faceplate in the first spatially separated substrate processing station and to the gas distribution faceplate in the second spatially separated substrate processing station; a third delivery conduit configured to deliver the first precursor through a fifth heating zone to a gas distribution faceplate in a third spatially separated substrate processing station and a sixth heating zone to a gas distribution faceplate in a fourth spatially separated substrate processing station; a fourth delivery conduit configured to deliver the second precursor through a seventh heating zone to a gas distribution faceplate in the third spatially separated substrate processing station and an eighth heating zone to a gas distribution faceplate in the fourth spatially separated substrate processing station; and a first supply conduit connected to a first precursor supply and the first delivery conduit and the third delivery conduit and a second supply conduit connected to a second precursor supply and the second delivery conduit and the fourth delivery conduit, a ninth heating zone configured to heat the first supply conduit and a tenth heating zone configured to heat the second supply conduit independently from the ninth heating zone, wherein the first, second, third, fourth, fifth, sixth, seventh and eighth heating zones are independently are heated

Additional embodiments of the disclosure are directed to a method of maintaining deposition uniformity in a multiple station substrate processing chamber, the method comprising independently controlling eight precursor delivery conduit heating zones configured to heat a first precursor delivery conduit and a second precursor delivery conduit configured to deliver two different precursors to each of four spatially separated substrate processing stations within a multiple station substrate processing chamber wall; and independently controlling a first precursor supply conduit heating zone configured to heat a first precursor supply conduit configured to supply a first precursor to the each of four spatially separated substrate processing stations and a second precursor supply conduit heating zone configured to heat a second precursor supply conduit configured to supply a second precursor to the each of four spatially separated substrate processing stations, the spatially separated substrate processing stations configured to separately and simultaneously deposit a film on a substrate placed within each of the four spatially separated substrate processing stations.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 shows a cross-sectional isometric view of a multiple station substrate processing chamber in accordance with one or more embodiment of the disclosure;

FIG. 2 shows a top plan view of a multiple station substrate processing chamber according to one or more embodiments;

FIG. 3 shows an isometric view of the delivery conduits and supply conduits of the multiple station substrate processing chamber shown in FIG. 2; and

FIG. 4 is a flowchart of a method according to one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor substrates. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus for example, where a film/layer or partial film/layer has been deposited onto a substrate surface, the exposed surface of the newly deposited film/layer becomes the substrate surface.

As used in this specification and the appended claims, the terms “precursor”, “reactant”, “reactive gas” and the like are used interchangeably to refer to any gaseous species that can react with the substrate surface.

One or more embodiments of the disclosure are directed to multiple station substrate processing chamber having spatial separation between four or more substrate processing stations. Some embodiments advantageously provide apparatus and methods to maintain separation of incompatible gases. Some embodiments advantageously provide apparatus and methods including optimizable plasma processing. Some embodiments advantageously provide apparatus and methods that allow for a differentiated thermal dosing environment, a differentiated plasma treatment environment and other environments.

One or more embodiments of the disclosure are directed to processing chambers having four spatially separated processing environments, also referred to as processing stations. Some embodiments have more than four and some embodiments have less than four. The processing environments can be mounted coplanar to the substrate(s) that are moving in a horizontal plane. The process environments are placed in a circular arrangement. A rotatable structure with one to four (or more) individual substrate heaters mounted thereon moves the substrates in a circular path with a diameter similar to the process environments. Each heater may be temperature controlled and may have one or multiple concentric zones. For substrate loading, the rotatable structure could be lowered so that a vacuum robot could pick finished substrates and place unprocessed substrates on lift pins located above each substrate heater (in the lower Z position). In operation, each substrate can be under an independent environment until the process is finished, then rotatable structure can rotate to move the substrates on the heaters to the next environment (90° rotation for four stations, 120° rotation if three stations) for processing.

Some embodiments of the disclosure advantageously provide spatial separation for ALD with incompatible gases. Some embodiments allow for higher throughput and tool resource utilization than a traditional time-domain or spatial process chamber. Each process environment can operate at a different pressure. The heater rotation has Z direction motion so each heater can be sealed into a chamber.

Some embodiments advantageously provide plasma environments that can include one or more of microwave, inductively couple plasma (ICP), parallel plate capacitively couple plasma (CCP) or three electrode CCP. The entire substrate can be immersed in plasma; eliminating the plasma damage from non-uniform plasma across the substrate.

Precursors are delivered in each of the four substrate processing stations through gas distribution faceplates, which include small gas holes (<200 μm), a high number of gas holes (many thousands to greater than 10 million). The small size and high number gas holes can be created by laser drilling or dry etching. However precisely these gas holes are formed in the gas distribution faceplates, manufacturing tolerances results in the diameters of the gas holes varying among gas distribution faceplates. These manufacturing tolerances that result in different gas hole diameters cause film thickness nonuniformities in different substrate processing stations of a multiple station substrate processing chamber. It was determined that existing temperature control at the individual substrate processing stations has been insufficient to adjust control film deposition nonuniformity among the four substrate processing stations. Existing hardware has failed to address film thickness nonuniformity.

Advantageously, embodiments of the present disclosure provide improved temperature control to provide improved film thickness nonuniformity among the four individual substrate processing stations in a multiple station substrate processing chamber comprising four or more substrate processing chamber. Advantageously, by providing individual and independently controlled heating zones for each of two precursors delivered to each of the four substrate processing stations provides better film deposition uniformity in chemical vapor deposition (CVD) and atomic layer deposition (ALD) processes performed simultaneously in four substrate processing stations. Additionally, in some embodiments, each of the two precursor supply conduits include independently controlled heating zones so that the temperature of the precursor delivered from a precursor supply (e.g., an ampoule or vessel) is tightly controlled. Advantageously, the multiple independently controlled heating zones for each precursor at each substrate processing chamber and the independently controlled heating zones for each precursor supply conduit provides better control of gas viscosity and gas flow conductance in each of the substrate processing chambers. This temperature control advantageously provides a control mechanism to adjust for gas distribution faceplate gas hole diameter variance in different gas distribution faceplates in each of the four substrate processing stations which causes deposition nonuniformity in the spatially separated substrate processing station in a multiple station substrate processing chamber.

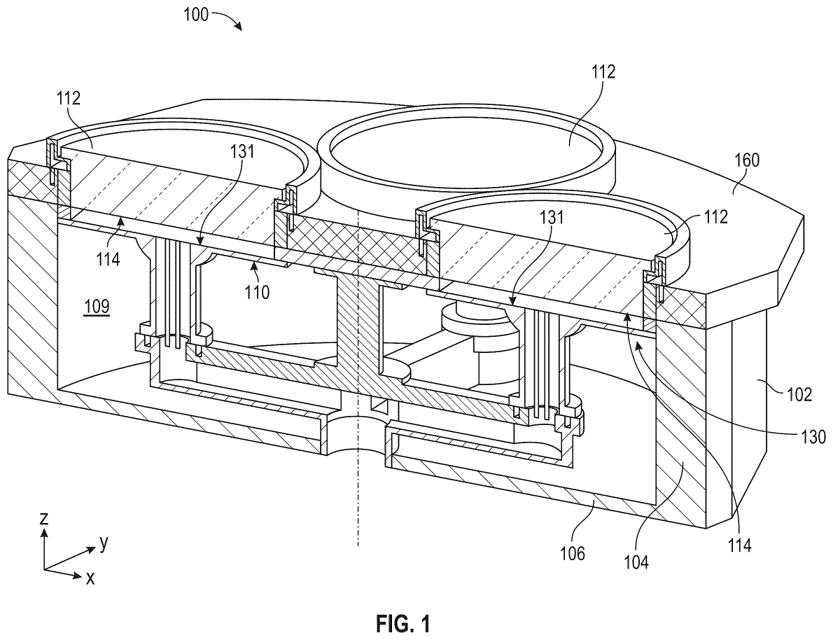

FIG. 1 illustrates a cross-sectional isometric view of a multiple station substrate processing chamber 100 in accordance with one or more embodiments of the disclosure. Some embodiments of the disclosure are directed to a multiple station substrate processing chamber 100 that incorporates a support assembly 150 and top plate 300.

The multiple station substrate processing chamber 100 has a housing 102 including a chamber wall 104 and a bottom 106. The housing 102 along with the top plate 160 define an interior volume 109, also referred to as a processing volume.

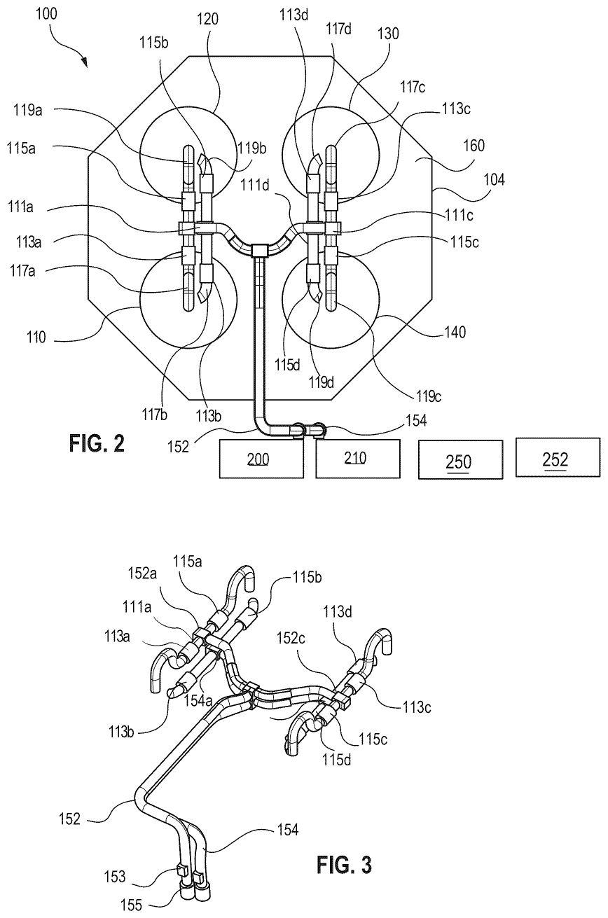

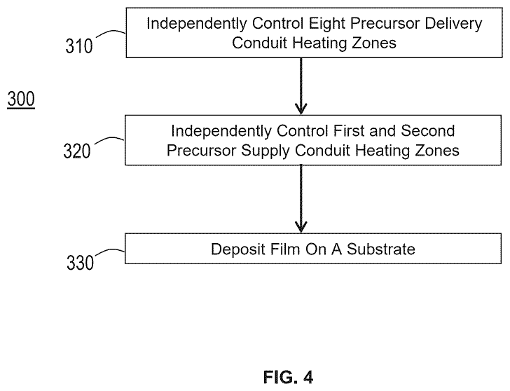

The multiple station substrate processing chamber 100 includes four spatially separated substrate processing stations 110, 120, 130 and 140 configured to separately and simultaneously deposit a film on a substrate (not shown) placed within each of the four spatially separated substrate processing stations 110 are located in the interior volume 109 of the housing 102 and are positioned in a circular arrangement around the rotational axis 211 of the support assembly. The four spatially separated substrate processing stations 110 are spatially arranged around the interior volume 109 of the multiple station substrate processing chamber 100. Each of the four spatially separated substrate processing stations 110, 120, 130, and 140 (shown in FIG. 2) comprises a gas injector 112 having a gas distribution faceplate 114. In some embodiments, the gas distribution faceplates 114 of each of the gas injectors 112 are substantially coplanar. The four spatially separated substrate processing stations 110, 120, 130 and 140 are defined as a region in which processing can occur. For example, each of the four spatially separated substrate processing stations 110 can be defined by a support surface and the gas distribution faceplate 114 of the gas injectors 112.

The four spatially separated substrate processing stations 110, 120, 130, and 140 can be configured to perform any suitable process and provide any suitable process conditions. The type of gas injector 112 used will depend on, for example, the type of process being performed and the type of showerhead or gas injector. For example, a process station 110 configured to operate as an atomic layer deposition apparatus may have a showerhead or vortex type gas injector. In some embodiments, the four spatially separated substrate processing stations 110 can be configured to operate as a plasma station may have one or more electrode and/or grounded plate configuration to generate a plasma while allowing a plasma gas to flow toward the substrate.

Referring now to FIG. 2 a top plan view of a, multiple station substrate processing chamber 100 is shown including the chamber wall 104 enclosing four spatially separated substrate processing stations 110, 120, 130, and 140 configured to separately and simultaneously deposit a film on a substrate placed within each of the four spatially separated substrate processing stations 110, 120, 130, and 140.

A first delivery conduit 111 is configured to deliver a first precursor such as a gaseous precursor through a first heating zone 113a to a gas distribution faceplate 131 (shown in FIG. 1) in a first spatially separated substrate processing station 110 and a second heating zone 115a to a gas distribution faceplate 131 in a second spatially separated substrate processing station 120. The first delivery conduit 111a splits to provide a first station outlet 117a and a second station outlet 119a to supply the first precursor to the respective first substrate processing station 110 and the second substrate processing station 120.

There is a second delivery conduit 111b configured to deliver a second precursor through a third heating zone 113b to the gas distribution faceplate 131 in the first spatially separated substrate processing station 110 and a fourth heating zone 115b to a gas distribution faceplate 131 in the first spatially separated substrate processing station 110 and to the gas distribution faceplate 131 in the second spatially separated substrate processing station 120. The second delivery conduit 111b splits to provide a third station outlet 117b and a fourth station outlet 119b to supply the second precursor to the respective first substrate processing station 110 and the second substrate processing station 120.

There is a third delivery conduit 111c configured to deliver the first precursor through a fifth heating zone 113c to a gas distribution faceplate 131 in a third spatially separated substrate processing station 130 and a sixth heating zone 115c to a gas distribution faceplate 131 in a fourth spatially separated substrate processing station 140. The third delivery conduit 111c splits to provide a third station outlet 117c to deliver the first precursor to the third substrate processing station 130 and a fourth station outlet 119c to deliver the first precursor to the fourth substrate processing station 140.

There is a fourth delivery conduit 111d configured to deliver the second precursor through a seventh heating zone 113d to a gas distribution faceplate 131 in the third spatially separated substrate processing station 130 and an eighth heating zone 115d to a gas distribution faceplate in the fourth spatially separated substrate processing station 140. The fourth delivery conduit 111d splits to provide a seventh station outlet 117d to deliver the second precursor to the third substrate processing station 130 and to provide an eighth station outlet 119d to deliver the second precursor to the fourth substrate processing station 140.

A first supply conduit 152 is connected to a first precursor supply 200 and the first delivery conduit 111a and the third delivery conduit 111c. A second supply conduit 154 is connected to a second precursor supply 210 and the second delivery conduit 111b and the fourth delivery conduit 111d. There is a ninth heating zone 153 configured to heat the first supply conduit 152 and a tenth heating zone 155 configured to heat the second supply conduit 154 independently from the ninth heating zone 153. In some embodiments, the first heating zone 113a, the second heating zone 115a, the third heating zone 113b, the fourth heating zone 115b, the fifth heating zone 113c, the sixth heating zone 115c, the seventh heating zone 113d and the eighth heating zone 115d are all heated independently from the other heating zones.

The supply conduits and the delivery conduits can be a pipe or tubing made from any suitable material that is not corroded or degraded by the precursors that flow through the conduits. In some embodiments, the conduits are made from a metal such as stainless steel. In other embodiments, the conduits are made from a polymeric or plastic material. The conduits according to some embodiments can be made from composite materials.

As used herein according to one or more embodiments, a “heating zone” refers to a region of the conduit that is supplied with energy to increase or decrease the temperature of the conduit. While the heating zones are shown at discrete locations on in the Figures, it will be appreciated if the heating zones can extend the entire length of the conduit that each respective heating zone is associated with. In a specific embodiment, the ninth heating zone 153 and the tenth heating zone 155 each respectively extend the entire length of the first supply conduit 152 and the second supply conduit. More specifically, the ninth heating zone 153 in some embodiments extends from the first precursor supply 200, which can be an ampoule containing a first precursor to the points 152a, 152c at which the first supply conduit 152 connects to the first delivery conduit 111a and the third delivery conduit 111c. Likewise, in some embodiments, the tenth heating zone 155 extends from the second precursor supply 210, which can be an ampoule containing a second precursor to points 154a, 154b at which the second supply conduit 154 connects to the second delivery conduit 111b and the fourth delivery conduit 111d.

The precursors can be any suitable precursors, which will depend on the film to be deposited by a CVD or ALD process. Silicon precursors can include silane, siloxanes and/or silicon halides. Oxygen precursors can include oxygen, N₂O, or H₂O. Metal precursors to deposit copper, titanium, tungsten, molybdenum, as well as oxides and or nitrides of metals can be deposited using any organometallic precursors used to deposit metals by CVD or ALD. According to one or more embodiments, the chamber and method described herein can be used to deposit metal oxides, organic films, TEOS, and ONON (oxide/nitride/oxide/nitride) stack based films.

The multiple station substrate processing chamber shown in FIG. 2 according to some embodiments further comprises a first controller 250 configured to independently control the first through eighth heating zones and the ninth and tenth heating zones. In one or more embodiments, each of the first through eighth heating zones and the ninth and tenth heating zones each comprise an independent power supply 252. The power supplies can be integrated with the respective zones and controlled wirelessly or by a wired connection. Alternatively, a power supply as shown FIG. 3 can independently control each of the first through eighth heating zones and the ninth heating zone 153 and the tenth heating zone 155. Thus a first power supply is integral with the first heating zone 113a, a second power supply is integral with the second heating zone, a third power supply is integral with the third heating zone 113b, a fourth power supply is integral with the fourth heating zone 115b, a fifth power supply is integral with the fifth heating zone 113c, a sixth power supply is integral with the sixth heating zone 115c, a seventh power supply is integral with the seventh heating zone 113d, and an eighth power supply is integral with the eighth heating zone 115d. The ninth heating zone 153 can have a ninth integral power supply and the tenth heating zone 155 can have a tenth integral power supply. In some embodiments, the power supplies for each of the first through tenth zones are separate from the heating zones.

In some embodiments, each of the first through eighth heating zones and the ninth and tenth heating zones comprise a heating jacket connected to the independent power supply for each of the first through eighth heating zones and the ninth and tenth heating zones. The heating jacket is simply a wrap around the outside of the conduit associated with each respective heating zone. Thus the heating jacket is not easily visible in FIG. 2 or FIG. 3 because it is wrapped around the conduit.

In one of more embodiments the substrate in each of the four spatially separated processing stations remains in one of the four spatially separated processing stations and does not travel between the four spatially separated processing stations.

In some embodiments, the first controller 250 is configured to adjust heat supplied to at least one of the first through eighth heating zones and the ninth and tenth heating zones to correct deposition nonuniformity in one or more of the four spatially separated substrate processing stations. In some embodiments, the heat supplied to at least one of the first through eighth heating zones and the ninth and tenth heating zones is adjustable based deposition uniformity results obtained from the first through the fourth spatially separated substrate processing stations. In one or more embodiments, increased heat in at least one of the first through eighth heating zones increases a flow conductance of the first precursor flowing through the gas distribution faceplate. In this case, the precursor may have a viscosity that increases with decreasing temperature, and increasing the temperature of the precursor will decrease the viscosity of the precursor. As discussed above, since the gas holes in a gas distribution faceplate 131 may vary in diameter between and among the different substrate processing stations due to manufacturing tolerance and variability, according to one or more embodiments, the temperatures can be tightly controlled by the chamber described herein according to one or more embodiments to compensate for the variability in the gas hole opening diameter.

The first controller 250 can have a processor, a memory coupled to the processor, input/output devices coupled to the processor, and support circuits configured to communicate between the different components of the multiple zone substrate processing chamber. The memory can include one or more of transitory memory (e.g., random access memory) and non-transitory memory (e.g., storage).

The memory or computer-readable medium, of the processor may be one or more of readily available memory such as random access memory (RAM), read-only memory (ROM), floppy disk, hard disk, or any other form of digital storage, local or remote. The memory 394 can retain an instruction set that is operable by the processor 392 to control parameters and components of the multiple station substrate processing chamber 100. The support circuits are coupled to the processor for supporting the processor in a conventional manner. Circuits may include, for example, cache, power supplies, clock circuits, input/output circuitry, subsystems, and the like.

Processes may generally be stored in the memory as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

In some embodiments, the first controller 250 has one or more configurations to execute individual processes or sub-processes. The controller can be connected to and configured to operate intermediate components to perform the functions of the methods. For example, the controller can be connected to and configured to control one or more of gas valves, actuators, motor, heating zones, vacuum control, etc.

The first controller 250 of some embodiments has one or more configurations selected from: a configuration to power a heater; a configuration to read temperature from temperature sensors; a configuration to provide power to the heater based on temperatures read from temperature sensors; a configuration to operate a motor/actuator to level the chamber lid; a configuration to provide a flow of gas to the station separation purge channel or a configuration to provide a flow of gas to the plurality of angular purge channels.

Referring now to FIG. 3, another aspect of the disclosure pertains to a method 300 of maintaining deposition uniformity in a multiple station substrate processing chamber. In one or more embodiments the method comprises at 310 independently controlling eight precursor delivery conduit heating zones configured to heat a first precursor delivery conduit and a second precursor delivery conduit configured to deliver two different precursors to each of four spatially separated substrate processing stations within a multiple station substrate processing chamber wall. The method further comprises at 320 independently controlling a first precursor supply conduit heating zone configured to heat a first precursor supply conduit configured to supply a first precursor to the each of four spatially separated substrate processing stations and a second precursor supply conduit heating zone configured to heat a second precursor supply conduit configured to supply a second precursor to the each of four spatially separated substrate processing stations, the spatially separated substrate processing stations configured to separately and simultaneously deposit a film on a substrate at 330 placed within each of the four spatially separated substrate processing stations.

In some embodiments, the method comprises increasing heat to at least one of the eight precursor delivery conduit heating zones to increase flow conductance of the first precursor or the second precursor to at least one of the each of four spatially separated substrate processing stations. As discussed herein, increasing the heat to at least one of the eight precursor delivery conduit heating zones increases a rate of deposition of a film to the at least one of the each of four spatially separated substrate processing stations.

According to one or more embodiments, controlled temperature adjustment based on thickness non-uniformity for each station is utilized to more precisely control gas flow conductance through each substrate processing station in a multiple station substrate processing chamber. Gas flow conductance, gas viscosity and pressure as a function of temperature is leveraged to be a process knob to achieve better control of thickness non-uniformity between and among the spatially separated substrate processing stations 110, 120, 130 and 140. Advantageously, according to one or more embodiments, thickness uniformity among the four spatially separated processing chambers is expected to improve upon a thickness nonuniformity of about 3% to closer to 1% nonuniformity.

The method according to one or more embodiments can further comprise increasing heat to at least one of the first precursor supply conduit heating zone and the second precursor supply conduit heating zone. The method can include using the multiple station substrate processing chamber comprising the first through eighth heating zones and a ninth heating zone and a tenth heating zone.

In some embodiments, each of the first through eighth heating zones and the ninth and the tenth heating zone comprise a heating jacket connected to an independent power supply for each of the first through eighth heating zones and the ninth heating zone and the tenth heating zone.

According to certain embodiments of the method, a substrate in each of the four spatially separated processing stations remains in one of the four spatially separated processing stations and does not travel between the four spatially separated processing stations. In some embodiments, a first controller adjusts heat supplied to at least one of the first through eighth heating zones and the ninth heating zone and the tenth heating zones to correct deposition nonuniformity in one or more of the four spatially separated substrate processing stations.

In some embodiments of the method, the heat supplied to at least one of the first through eighth heating zones and the ninth heating zone and the tenth heating zone is adjustable based deposition uniformity results obtained from the first through the fourth spatially separated substrate processing stations In some embodiments of the method, increased heat in at least one of the first through eighth heating zones increases a flow conductance of one of the first precursor and the second precursor flowing through the gas distribution faceplate.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A multiple station substrate processing chamber comprising:
a chamber wall enclosing four spatially separated substrate processing stations configured to separately and simultaneously deposit a film on a substrate placed within each of the four spatially separated substrate processing stations;
a first delivery conduit configured to deliver a first precursor through a first heating zone to a gas distribution faceplate in a first spatially separated substrate processing station and a second heating zone to a gas distribution faceplate in a second spatially separated substrate processing station;
a second delivery conduit configured to deliver a second precursor through a third heating zone to the gas distribution faceplate in the first spatially separated substrate processing station and a fourth heating zone to a gas distribution faceplate in the first spatially separated substrate processing station and to the gas distribution faceplate in the second spatially separated substrate processing station;
a third delivery conduit configured to deliver the first precursor through a fifth heating zone to a gas distribution faceplate in a third spatially separated substrate processing station and a sixth heating zone to a gas distribution faceplate in a fourth spatially separated substrate processing station;
a fourth delivery conduit configured to deliver the second precursor through a seventh heating zone to a gas distribution faceplate in the third spatially separated substrate processing station and an eighth heating zone to a gas distribution faceplate in the fourth spatially separated substrate processing station; and
a first supply conduit connected to a first precursor supply and the first delivery conduit and the third delivery conduit and a second supply conduit connected to a second precursor supply and the second delivery conduit and the fourth delivery conduit, a ninth heating zone configured to heat the first supply conduit and a tenth heating zone configured to heat the second supply conduit independently from the ninth heating zone, wherein the first, second, third, fourth, fifth, sixth, seventh and eighth heating zones are independently are heated.

2. The multiple station substrate processing chamber of claim 1, further comprising a first controller configured to independently control the first through eighth heating zones and the ninth heating zone and the tenth heating zone.

3. The multiple station substrate processing chamber of claim 2, wherein each of the first through eighth heating zones and the ninth heating zone and the tenth heating zone each comprise an independent power supply.

4. The multiple station substrate processing chamber of claim 3, wherein the each of the first through eighth heating zones and the ninth and tenth heating zones comprise a heating jacket connected to the independent power supply for each of the first through eighth heating zones and the ninth heating zone and the tenth heating zone.

5. The multiple station substrate processing chamber of claim 2, wherein the substrate in each of the four spatially separated processing stations remains in one of the four spatially separated processing stations and does not travel between the four spatially separated processing stations.

6. The multiple station substrate processing chamber of claim 2, wherein the first controller is configured to adjust heat supplied to at least one of the first through eighth heating zones and the ninth heating zone and the tenth heating zone to correct deposition nonuniformity in one or more of the four spatially separated substrate processing stations.

7. The multiple station substrate processing chamber of claim 6, wherein the heat supplied to at least one of the first through eighth heating zones and the ninth heating zone and the tenth heating zone is adjustable based deposition uniformity results obtained from the first through the fourth spatially separated substrate processing stations.

8. The multiple station substrate processing chamber of claim 7, wherein increased heat in at least one of the first through eighth heating zones increases a flow conductance of the first precursor flowing through the gas distribution faceplate.

9. A method of maintaining deposition uniformity in a multiple station substrate processing chamber, the method comprising:
independently controlling eight precursor delivery conduit heating zones configured to heat a first precursor delivery conduit and a second precursor delivery conduit configured to deliver two different precursors to each of four spatially separated substrate processing stations within a multiple station substrate processing chamber wall; and
independently controlling a first precursor supply conduit heating zone configured to heat a first precursor supply conduit configured to supply a first precursor to the each of four spatially separated substrate processing stations and a second precursor supply conduit heating zone configured to heat a second precursor supply conduit configured to supply a second precursor to the each of four spatially separated substrate processing stations, the spatially separated substrate processing stations configured to separately and simultaneously deposit a film on a substrate placed within each of the four spatially separated substrate processing stations.

10. The method of claim 9, further comprising increasing heat to at least one of the eight precursor delivery conduit heating zones to increase flow conductance of the first precursor or the second precursor to at least one of the each of four spatially separated substrate processing stations.

11. The method of claim 9, wherein increasing the heat to at least one of the eight precursor delivery conduit heating zones increases a rate of deposition of a film to the at least one of the each of four spatially separated substrate processing stations.

12. The method of claim 9, further comprising increasing heat to at least one of the first precursor supply conduit heating zone and the second precursor supply conduit heating zone.

13. The method of claim 9, wherein the multiple station substrate processing chamber comprises a first through eighth heating zones and a ninth and a tenth heating zone.

14. The method of claim 13, wherein each of the first through eighth heating zones and the ninth and the tenth heating zone comprise a heating jacket connected to an independent power supply for each of the first through eighth heating zones and the ninth heating zone and tenth heating zone.

15. The method of claim 13, wherein a substrate in each of the four spatially separated processing stations remains in one of the four spatially separated processing stations and does not travel between the four spatially separated processing stations.

16. The method of claim 15, wherein a first controller adjusts heat supplied to at least one of the first through eighth heating zones and the ninth heating zone and the tenth heating zone to correct deposition nonuniformity in one or more of the four spatially separated substrate processing stations.

17. The method of claim 16, wherein the heat supplied to at least one of the first through eighth heating zones and the ninth heating zone and the tenth heating zones is adjustable based deposition uniformity results obtained from the first through the fourth spatially separated substrate processing stations.

18. The method of claim 17, wherein increased heat in at least one of the first through eighth heating zones increases a flow conductance of one of the first precursor and the second precursor flowing through the gas distribution faceplate.
